(19) United States
(12) Patent Application Publication
(10) Pub. No.: US 2007/0151841 A1
(43) Pub. Date: Jul. 5, 2007

(54) Flexible magnetron including partial rolling support and centering pins

(75) Inventors: Makoto Inagawa, Palo Alto, CA (US); Akihiro Hosokawa, Cupertino, CA (US); Hien-Minh Huu Le, San Jose, CA (US); Ilya Lavitsky, San Francisco, CA (US); John M. White, Hayward, CA (US); Todd Martin, Mountain View, CA (US); Bradley O. Stimson, Monte Sereno, CA (US)

Correspondence Address: LAW OFFICES OF CHARLES GUENZER;ATTN: APPLIED MATERIALS, INC., 2211 PARK BOULEVARD, P.O. BOX 60729, PALO ALTO, CA, 94306, US

(73) Assignee: Applied Materials, Inc., Santa Clara, CA (US)

(21) Appl. No.: 11/601,576

(22) Filed: Nov. 17, 2006

Related U.S. Application Data
(63) Continuation-in-part of application No. 11/347,667, filed on Feb. 3, 2006.
Application No. 11/347,667 is a continuation-in-part of application No. 11/301,849, filed on Dec. 12, 2005.
Application No. 11/301,849 is a continuation-in-part of application No. 11/282,798, filed on Nov. 17, 2005.
(60) Provisional application No. 60/835,680, filed on Aug. 4, 2006.

(51) Int. Cl. C23C 14/32; C23C 14/00

(52) U.S. Cl. 204/192.1; 204/298.16

(57) ABSTRACT

A magnetron scanning and support mechanism in which the magnetron is partially supported from an overhead scanning mechanism through multiple springs coupled to different horizontal locations on the magnetron and partially supported from below at multiple locations on the target, on which it slides or rolls. In one embodiment, the yoke plate is continuous and uniform. In another embodiment, the magnetron's magnetic yoke is divided into two flexible yokes, for example, of complementary serpentine shape and each supporting magnets of respective polarity. In another embodiment, the target and magnetron are divided into respective strips separated by other structure. Each magnetron strip is supported partially from above from a common scanning plate and partially on a respective target strip. A centering mechanism may align the different magnetron strips.

### RELATED APPLICATIONS

This application claims benefit of provisional application 60/835,680, filed Aug. 4, 2006. It is also a continuation in part of Ser. No. 11/347,667, filed Feb. 3, 2006 and a continuation in part of Ser. No. 11/301,849, filed Dec. 12, 2005, which is a continuation in part of Ser. No. 11/282,798, filed Nov. 17, 2005.

### FIELD OF THE INVENTION

The invention relates generally to sputter deposition in the fabrication of semiconductor integrated circuits. In particular, the invention relates to magnetrons scanned over the back of a sputtering target.

### BACKGROUND ART

Plasma magnetron sputtering has been long practiced in the fabrication of silicon integrated circuits. More recently, sputtering has been applied to depositing layers of materials onto large, generally rectangular panels of glass or other materials, for example, to form large flat panel displays for computer screens or televisions or the like.

Demaray et al. describe such a flat panel sputter reactor in U.S. Pat. No. 5,565,071, incorporated herein by reference in its entirety. Their reactor includes, as illustrated in the schematic cross section of FIG. 1, a rectangularly shaped sputtering pedestal electrode 12, which is typically electrically grounded, for holding a rectangular glass panel 14 or other substrate in opposition to a rectangular sputtering target assembly 16 within a vacuum chamber 18. The target assembly 16, at least the surface of which is composed of a metal to be sputtered, is vacuum sealed to the vacuum chamber 18 across an isolator 20. Typically, a target layer of the material to be sputtered is bonded to a backing plate in which cooling water channels are formed to cool the target assembly 16. A sputtering gas, typically argon, is supplied into the vacuum chamber 18 held at a pressure in the milliTorr range.

Advantageously, a back chamber 22 is vacuum sealed to the back of the target assembly 16 and is vacuum pumped to a low pressure, thereby substantially eliminating the pressure differential across the target assembly 16. Thereby, the target assembly 16 can be made much thinner. When a negative DC bias is applied to the conductive target assembly 16 with respect to the pedestal electrode 12 or other grounded parts of the chamber such as wall shields, the argon is ionized into a plasma. The positive argon ions are attracted to the target assembly 16 and sputter metal atoms from the target layer. The metal atoms are partially directed to the panel 14 and deposit thereon a layer at least partially composed of the target metal. Metal oxide or nitride may be deposited in a process called reactive sputtering by additionally supplying oxygen or nitrogen into the chamber 18 during sputtering of the metal.

To increase the sputtering rate, a magnetron 24 is conventionally placed in back of the target assembly 16. If it has a central pole 26 of one vertical magnetic polarity surrounded by an outer pole 28 of the opposite polarity to project a magnetic field within the chamber 18 and parallel to the front face of the target assembly 16, under the proper chamber conditions a high-density plasma loop is formed in the processing space adjacent the target layer. The two opposed magnetic poles 26, 28 are separated by a substantially constant gap defining the track of the plasma loop. The magnetic field from the magnetron 24 traps electrons and thereby increases the density of the plasma and as a result increases the sputtering rate of the target 16. The relatively small widths of the linear magnetron 24 and of the gap produces a higher magnetic flux density. The closed shape of the magnetic field distribution along a single closed track prevents the plasma from leaking out the ends.

The size of the rectangular panels being sputter deposited is continuing to increase. One generation processes a panel having a size of 1.87 m×2.2 m and is called 40K because its total area is greater than 40,000 cm². A follow-on generation called 50K has a size of greater than 2 m on each side.

These very large sizes have imposed design problems in the magnetron since the target spans a large area and the magnetron is quite heavy but nonetheless the magnetron should be scanned over the entire area of the target and in close proximity to it.

### SUMMARY OF THE INVENTION

A magnetron for use in a plasma sputter chamber is partially supported from below on the back of the target or target assembly on which it can roll or slide and partially supported from above by spring-loaded supports from a scanning mechanism. Thereby, the magnetron may track the shape of a non-flat target as it being scanned across the back of the target.

In one series of embodiments, the sputter chamber includes a gantry or carriage which can move relative in a first direction to the chamber body through, for example, a first set of rollers, and which supports, for example, through a second set of rollers the magnetron for movement in a second direction. The gantry partially supports the magnetron from above through plural spring-loaded supports while rollers or other means partially support the magnetron from below on the target. The springs may be included in the second set of rollers or be included in members coupling trolleys engaging the second set of rollers to the magnetron. For example, the second set of rollers may suspend a support plate which supports the magnetron either through fixed means or spring-loaded means.

In one embodiment, the magnetron itself is flexible so that it may conform to the shape of the target. The magnetron may be is composed of two interleaved yoke plates separated by a gap sufficiently small that the yoke plates are magnetically coupled although structurally decoupled. Each of the yoke plates support magnets of a respective polarity. Each yoke plate is separately spring-supported from above and partially supported on the target by rollers or sliders. The yoke plates may be thin enough as to be flexible along their axes.

In an alternative embodiment, thin slots may be formed into a single yoke plate to structurally separate different portions of the yoke plate while they remain magnetically coupled.

In yet another embodiment, the target includes multiple target strips each including a strip target layer and strip yoke. Anodes or other features may separate the strips. Multiple strip magnetrons are separately resiliently supported on a common scanned support plate and individually roll on the respective target strips so that each target strip separately tracks a deformed target.

Grooves may be scored or otherwise machined partially through the yoke plate and transversely to its longitudinal axis so that different sections of the yoke plate are flexibly connected.

In another aspect of the invention, a yoke plate or other support member, preferably resiliently suspended from a support plate, is centered along its longitudinal axis by two centering mechanisms displaced along a separation axis of the yoke plate and associated magnetron. In an embodiment, the first centering mechanism includes a positioning bracket with a circular guide hole rotatably but closely capturing a first centering pin and the second centering mechanism includes a clocking bracket with an elongated guide hole closely capturing a second centering pin in a direction transverse to the separation axis but loosely capturing the second centering pin along the separation axis, thereby fixing the angular orientation.

### BRIEF DESCRIPTION OF THE DRAWINGS

FIG. 1 is a schematic cross-sectional view of a conventional plasma sputtering chamber configured for sputtering onto rectangular panels.

FIG. 2 is an orthographic view of a two-dimensional scanning mechanism usable in the sputtering chamber of FIG. 1.

FIG. 3 is a cross-sectional view of a first embodiment of a spring-loaded support.

FIG. 4 is an orthographic view, partially exploded, of two of the spring-loaded supports of FIG. 3.

FIG. 5 is a cross-sectional view of ball transfer usable to partially support the magnetron on the back of the target.

FIG. 6 is an orthographic view of the underside of the gantry and support plate partially supporting the magnetron from above through the spring-loaded supports.

FIG. 7 is a plan view of the retainers used to align magnets on the yoke plate.

FIG. 8 is an orthographic view of the gantry partially supporting the magnetron in a second embodiment of the invention.

FIG. 9 is an exploded isometric view of a spring-loaded roller assembly supported on the gantry of FIG. 8.

FIG. 10 is a cross-sectional view of the roller assembly of FIG. 9.

FIG. 11 is a schematic cross-sectional view of a third embodiment of the invention including a flexible magnetron.

FIG. 12 is an orthographic view of interleaved yoke plates and the support plate in the third embodiment.

FIG. 13 is an exploded orthographic view of part of FIG. 12.

FIG. 14 is a plan view of a yoke plate having narrow parallel slots allowing the plate to flex.

FIG. 15 is a schematic cross-sectional view of a sputter chamber having multiple targets.

FIG. 15 is an orthographic view generally from above of a scannable support plate supporting multiple magnetrons.

FIG. 16 is an orthographic view generally from below of the scannable support plate and multiple magnetrons of FIG. 15 including a division of each magnetron into flexibly connected sections.

FIG. 17 is a plan view of one of the magnetrons of FIG. 16 having a scored yoke plate.

FIG. 18 is a cross-sectional view of the magnetron of FIG. 17 having the scored yoke plate and separate retainer sections.

FIG. 19 is a cross-sectional view of a yoke plate resiliently supported from a support plate.

FIG. 20 is an cross-sectional view of roller ball assembly and spring support.

FIG. 21 is a bottom plan view of one embodiment of a magnet arrangement in a strip magnetron.

FIG. 22 is a bottom plan view of strip magnetron incorporating a centering mechanism including positioning and clocking brackets.

FIG. 23 is an orthographic view of a positioning bracket with a circular guide hole.

FIG. 24 is a cross-sectional view of the positioning bracket of FIG. 23 closely capturing a centering pin.

FIG. 25 is an orthographic view of a clocking bracket with an elongated guide hole.

FIG. 26 is a cross-sectional view of the clocking bracket of FIG. 25 loosely capturing a centering pin.

### DETAILED DESCRIPTION OF THE PREFERRED EMBODIMENTS

Tepman in U.S. patent application Ser. No. 11/211,141, filed Aug. 24, 2005, incorporated herein by reference, and published in U.S. patent application publication 2006/0049040, addresses several of the problems of large magnetrons used for sputtering onto large panels or flexible sheets. The completed panel may incorporate thin-film transistors, plasma display, field emitter, liquid crystal display (LCD) elements, or organic light emitting diodes (OLEDs) and is typically directed to flat panel displays. Photovoltaic solar cells may similarly be fabricated. Related technology may be used for coating glass windows with optical layers. The material of the sputter deposited layer may be a metal, such as aluminum or molybdenum, transparent conductors, such as indium tin oxide (ITO), and yet other materials including silicon, metal nitrides and oxides.

Tepman discloses a nearly square magnetron of a size only somewhat less than that of the target in which the magnets are arranged to form a closed plasma loop of convolute shape in the form of either a spiral or folded structure. A scanning mechanism scans the magnetron in a dimensional scan pattern over the remaining area of the target to produce a more uniform sputtering profile. Le et al. explain further developments in this sputter chamber and its operation in U.S. patent application Ser. No. 11/484,333, filed Jul. 11, 2006, incorporated herein by reference.

Tepman describes two types of support structures for the magnetron. In the first type, the target supports the overhead magnetron through Teflon pads which are mounted on the bottom of the magnetron and which can easily slide over the back of the target under the urging of a horizontal pushing or pulling force applied to the magnetron supported on the target. In the second type, the magnetron is suspended from an overhead carriage mounted on the chamber frame in the form of a gantry which can scan the suspended target above the back of the target.

The target-supported magnetron closely tracks the shape of the target, thus reducing the non-uniformity in magnetic field in the plasma region. The gap between the magnetron and the target are closely controlled by the thickness of the pads so that gap can be advantageously minimized. However, the target-support magnetron has the disadvantage that the magnetron including its magnets can be quite heavy, for example, over one ton. The great weight imposes a great force upon the target, which should be relatively thin to allow the magnetic field to penetrate from the magnetron at its top to the processing region at its bottom. As a result, the target is bound to significantly bow under the weight of the magnetron it supports. Excessive bow creates a significant variation in the spacing between the target and the panel being sputter coated, which introduces its own non-uniformity.

The carriage-supported magnetron removes the weight of the magnetron from the target to a scanning mechanism mounted above it, but it has the disadvantage of mechanically decoupling the magnetron from the target. The thin target, even without additional loading, tends to bow. The bow in the shape of the target is often downward under the force of the target's own weight. However, in some circumstances the bow is upwards. The cause of the upward bow is not completely understood but according to one explanation the upward bow arises from the inward force exerted on the clamped target by a vacuum-pumped chamber. Furthermore, as sputtering continues over the lifetime of the target and increasingly erodes the target and decreases its thickness, the bow may change. Any spatial variation in the spacing between the magnetron and the target introduces a non-uniformity in the magnetic field at the front face of the target and hence a non-uniformity in the plasma density and a non-uniformity in the thickness of the film sputter deposited on the panel. For commercial production, the film thickness must be as uniform as possible. The conventional carriage-supported magnetron does not easily provide for adjusting the spacing, particularly variable spacing over the extent of the target.

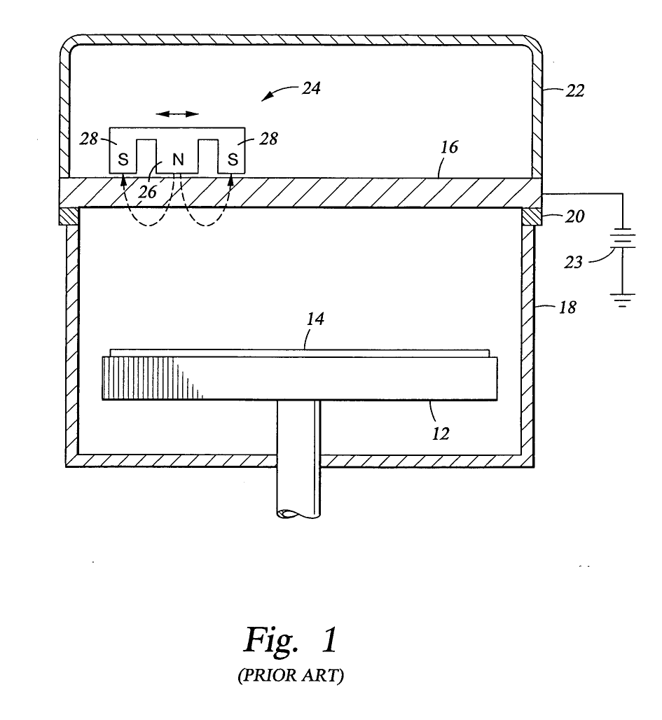

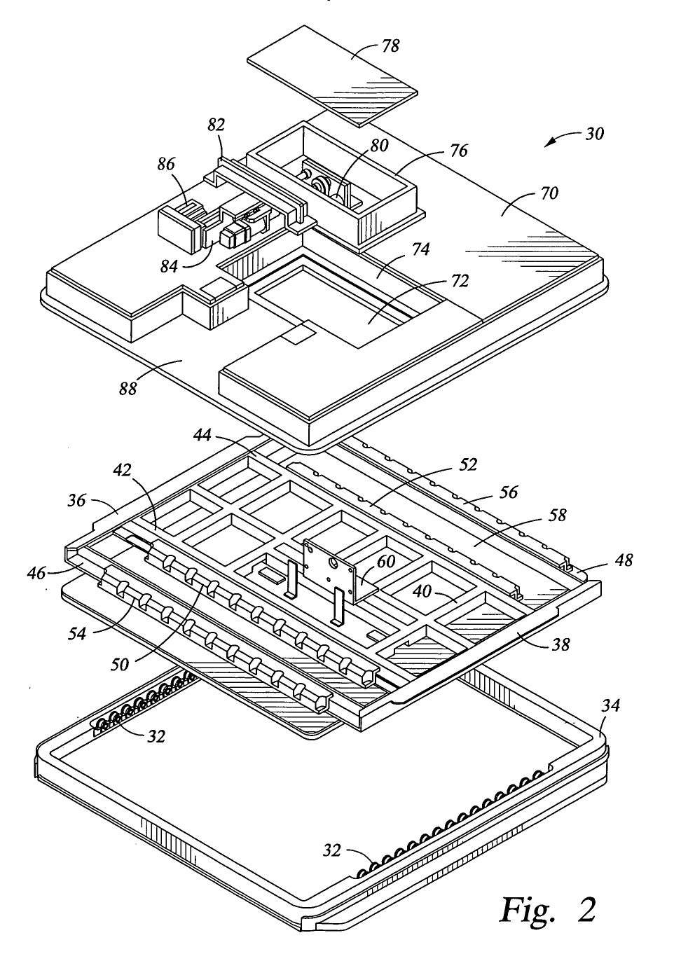

The invention may be applied to a magnetron scan mechanism assembly 30 illustrated in the exploded orthographic view of FIG. 2. Further details are available in the Tepman patent, from which the present design was derived. Two rows of rollers 32 are supported on opposed sides of a frame 34 constituting the sidewalls of the back chamber 22 of FIG. 1. The rollers 32 rollably support inverted frame rails 36, 38 supporting a gantry 40 between them. The gantry 40 includes four unillustrated rows of rollers on inner struts 42, 44 and outer struts 46, 48 for rollably supporting inverted gantry inner rails 50, 52 and outer rails 54, 56. The rails partially support a magnetron plate 58 including magnets on its lower side. The outer struts 46, 48 and outer rails 54, 56 provide additional support on the sides of the heavy magnetron plate 58 to reduce the amount of droop near the edges. In the Tepman configuration, the magnetron plate 58 is rigidly fixed to the inner rails 50, 52 so that the gantry 40 completely supports the magnetron plate 58. A base plate 60 is fixed to the frame structure forming the gantry 40.

It has been observed that the rails tend to twist under the load of the supported magnetron. The effect of the twist can be substantially eliminated by replicating the struts in closely spaced pairs with the rail replaced by a T-shaped support having cylindrical roller assemblies at each end of the cross bar supported on respective rails of the pair.

In one aspect of the present invention, the connection between the gantry 40 and the magnetron plate 58 is more flexible than a rigid mechanical connection so that the gantry 40 only partially supports the magnetron plate 58 and the spacing between the magnetron and the gantry may vary. By the rolling motion of the gantry 40 and rails 36, 38, 50, 52, 54, 56, the magnetron plate 58 can be moved in perpendicular directions inside the frame 34.

A magnet chamber roof 70 forming the top wall of the back chamber 22 of FIG. 1, is supported on and sealed to the frame 34 with the gantry structure disposed between them and provides the vacuum wall over the top of the chamber accommodating the magnetron. The magnet chamber roof 70 includes a rectangular aperture 72 and the bottom of a bracket recess 74. A bracket chamber 76 fits within the bracket recess 74 and is sealed to the chamber roof 70 around the rectangular aperture 72. A top plate 78 is sealed to the top of the bracket chamber 76 to complete the vacuum seal.

A gantry bracket 80 movably disposed within the bracket chamber 76 is fixed to the base plate 60 of the gantry 40. A support bracket 82, which is fixed to the exterior of the magnet chamber roof 70, and an intermediate angle iron 84 hold an actuator assembly 86 in an actuator recess 88 in the roof 70 outside the vacuum seal. The support bracket 82 further acts as part of the truss system in the magnet chamber roof 70. The actuator assembly 86 is coupled to the interior of the bracket chamber 76 through two sealed vacuum ports. As explained by Tepman, the actuator assembly 86 independently moves the gantry 40 in one direction by force applied through the gantry bracket 80 fixed to the gantry's base plate 60 and moves the magnetron plate 58 in the perpendicular direction by a belt drive with a belt having its ends fixed to the magnetron plate 58.

According to one aspect of the invention, the magnetron and its magnetron plate 58 are partially supported on the target assembly 16 and partially supported on the gantry 40 (also referred to as a carriage), which is scanning the magnetron over the back of the target 16. The partial support on the target causes the magnetron to follow the bow or other shape of the target, thus reducing the variation of the gap between the magnetron and the target and thus also allowing the size of the gap to be minimized. On the other hand, the partial and usually major support on the carriage removes some and usually most of the weight of the magnetron from the target, thus reducing the downward deflection of the target. Le et al. describe in parent U.S. patent applications Ser. No. 11/282,798, filed Nov. 17, 2005 and No. 11/301,849, filed Dec. 12, 2005, both incorporated herein by reference, a scanning mechanism which actively controls the vertical separation between the target and the magnetron, which the gantry suspends above the target. In contrast, a division of support between the target and gantry allows a passive method of tracking of the shape of the target.

It is appreciated that other types of mechanisms can allow the magnetron plate to glide along the back of the target. Pivoting roller wheels may be substituted the roller balls. Soft pads which do not wear the target may be substituted for the roller balls to allow the magnetron to slide on the back of the target. An example of the soft pads are cut from Teflon sheets and glued to the bottom of the retainers 154.

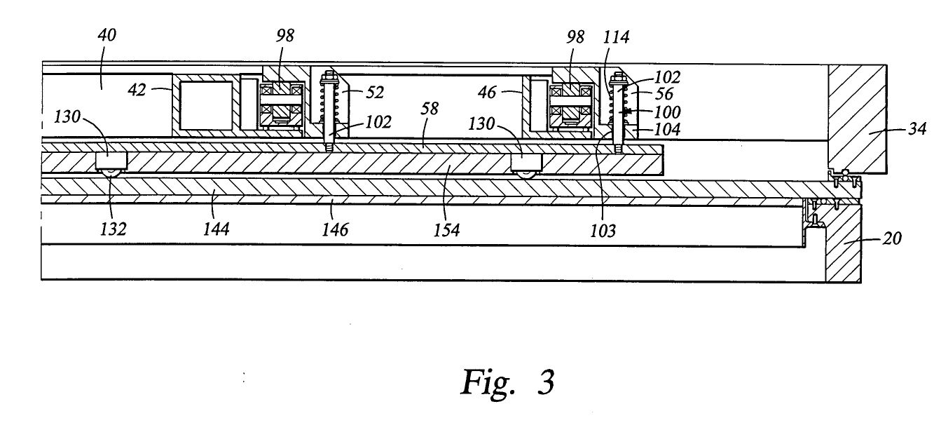

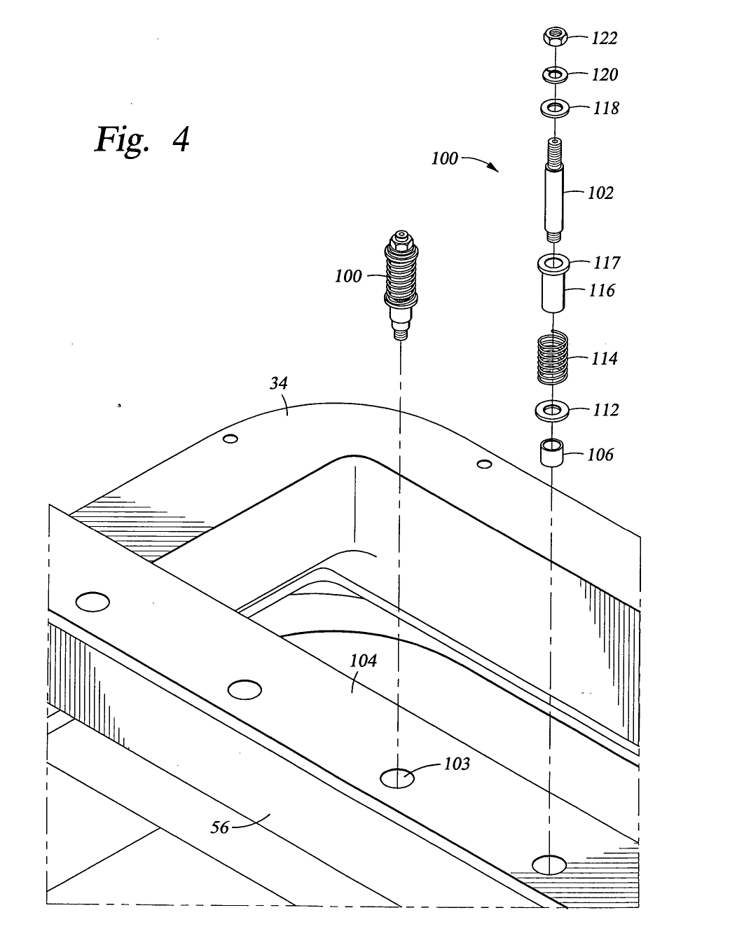

In a first embodiment of a resiliently supported magnetron, illustrated in the cross-sectional view of FIG. 3 and the partial orthographic view of FIG. 4, the magnetron plate 58 is partially supported from above by the vertically fixed rails 52, 56 (a similar structure is applied to the rails 50, 54 on the other side) rolling on cylindrical roller assemblies 98. The partial support if effected through multiple spring-loaded stud assemblies 100. Each stud assembly 100 includes a threaded stud 102 screwed into a tapped hole in the magnetron plate 58. The stud 102 extends through a corresponding hole 103 in a top arm 104 of the corresponding rail, for example, rail 56. The rail hole 103 includes a neck which supports a bushing 106, and the stud 102 passes through the bushing 106 and out the bottom of the hole 103 and is screwed into a threaded hole of the magnetron plate 58. The top of the bushing 106 extends above the arm 104 and supports a washer-shaped spring seat 112, which supports a bottom end of a spring 114. A tubular retainer 116 fits within the spring 114 with an upper flange 117 pressing against the top of the spring 114 over its top. The stud 102 passes through the retainer 116 and is laterally isolated from the spring 114 by the retainer 116. An upper washer 118 contacts the top end of the spring 116, and a lock washer 120 is placed above the upper washer 118. A nut 122 is threaded on the stud 102 threaded onto the magnetron plate 58 and thereby forces the flange 117 against the spring 114 thereby compressing it. The amount of spring compression determines the force (weight) borne by the top flange 104 of the rail 56 supporting the spring-loaded stud assembly 100 and the partial weight of the magnetron plate 58 supported by that stud assembly 100. The nuts 122 are not tightened sufficiently to force the magnetron plate 58 against the top arm 104 and the gantry 40. Instead a variable gap remains between them to allow the magnetron 58 to follow the shape of the target.

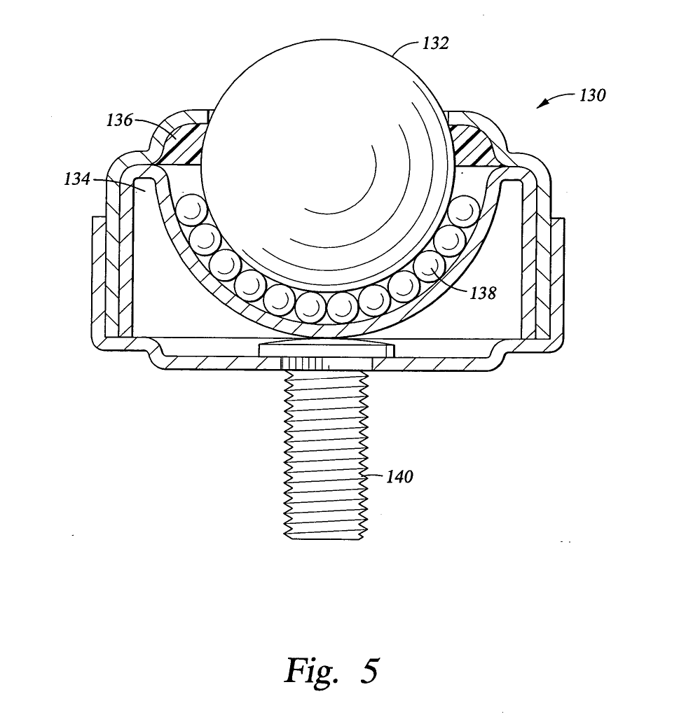

As shown in FIG. 3, the magnetron plate 58 is additionally partially supported on the target 12 through a plurality of roller ball assemblies 130 mounted on the bottom of the magnetron plate 58. An example of the roller ball assembly 130 is a ball transfer Model NSMS 1/4, available from Ball Transfer Systems of Perryopolis, Pa. and illustrated in the cross-sectional view of FIG. 5. A roller ball 132, preferably composed of a plastic such as nylon and having a relatively large diameter, for example, 1 inch (2.54 cm) protrudes from a housing 134 but is sealed to it by a seal 136. A large number of small bearing balls 138 rotatably support the roller ball 132 against a hemi-spherical surface of the housing 134. A stud 140 fixed to the housing 134 is screwed into a tapped hole at the bottom (upper in the operational orientation) of a recess formed at the bottom of the magnetron plate 58 or its magnet retainers 154 of sufficient diameter and depth to accommodate the housing 134. The depth of the recess determines the extent that the roller ball 132 protrudes below the magnetron, for example, 0.167 inch (4.2 mm).

The bottom of the roller ball 130 contacts the back of the target, specifically, a backing plate 144 of FIG. 3, in which liquid cooling channels are formed and to which is bonded a target layer 146 of the material to be sputtered. The backing plate 144 is supported and sealed to the isolator 20 on top of the chamber wall 18. The protrusion of the roller balls 130 from the magnetron plate 58 determines the gap between the magnetron 58 and the back of the target 144, 146.

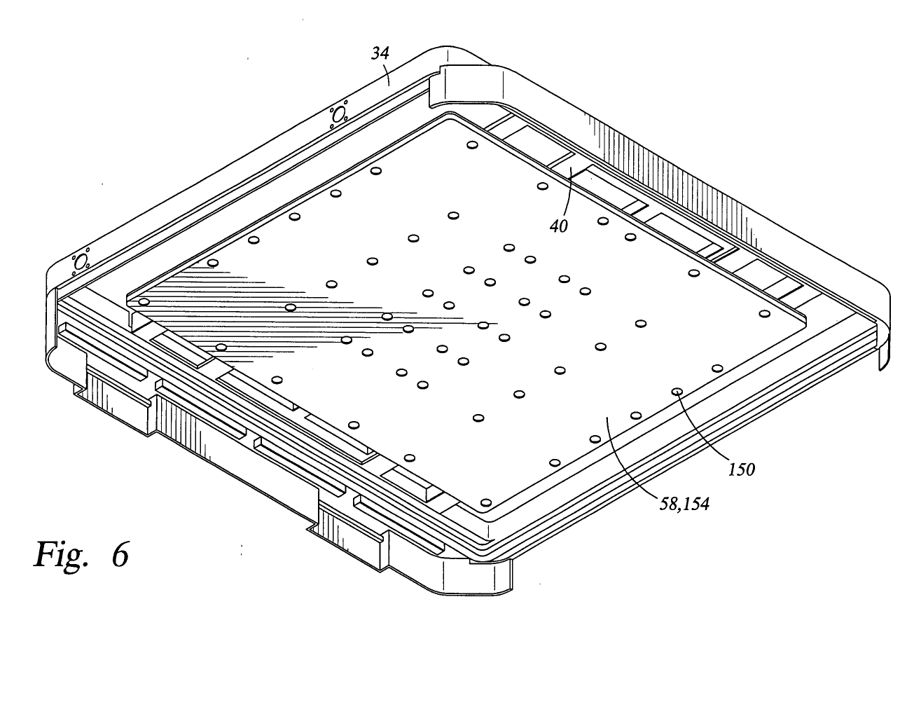

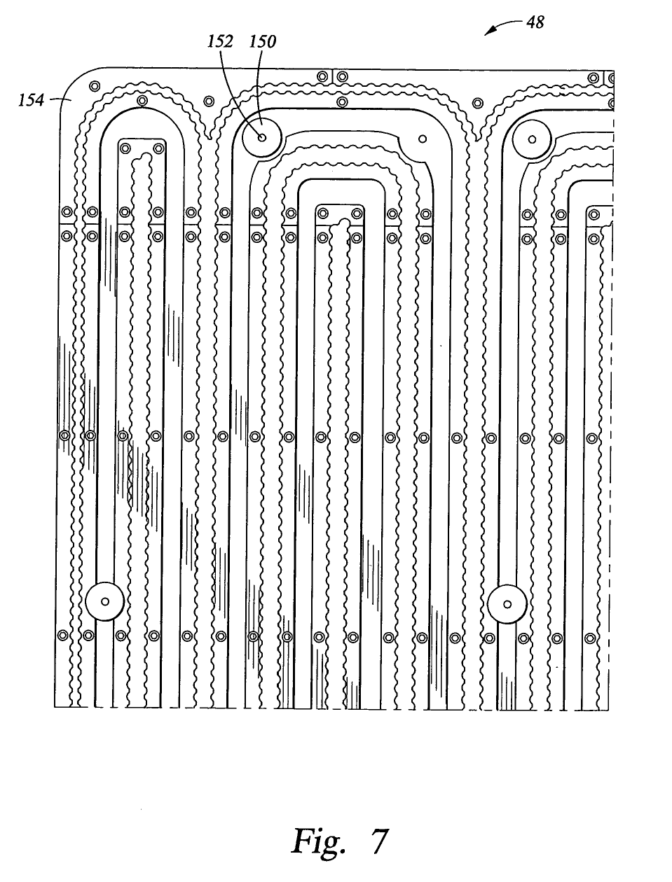

As shown in the orthographic view of FIG. 6, the generally planar bottom of the backing plate 58, which is composed of a magnetic material to act as a magnetic yoke, or its retainer 154 is machined with recesses 150 at its bottom. As shown in the plan view of FIG. 7, each recess 150 is formed as a through hole in the retainer 154 or as a blind hole in the magnetron plate 58 and a central tapped hole 152 is machined into the magnetron plate 58. The ball transfer stud 140 is threaded into the tapped hole 152. A large number of complexly shaped non-magnetic retainers 154, for example, of aluminum, are screwed to the backing plate 144 and have heights generally corresponding to the length of cylindrical magnets which are held between serrated edges of the retainers 154. The recesses 150 for the roller ball assemblies 130 are located on the sides of the retainers 154 away from the magnets. The gap between the magnetron and the target is determined by the amount that the roller ball 132 protrudes beyond the end of the magnets held in the retainers 154.

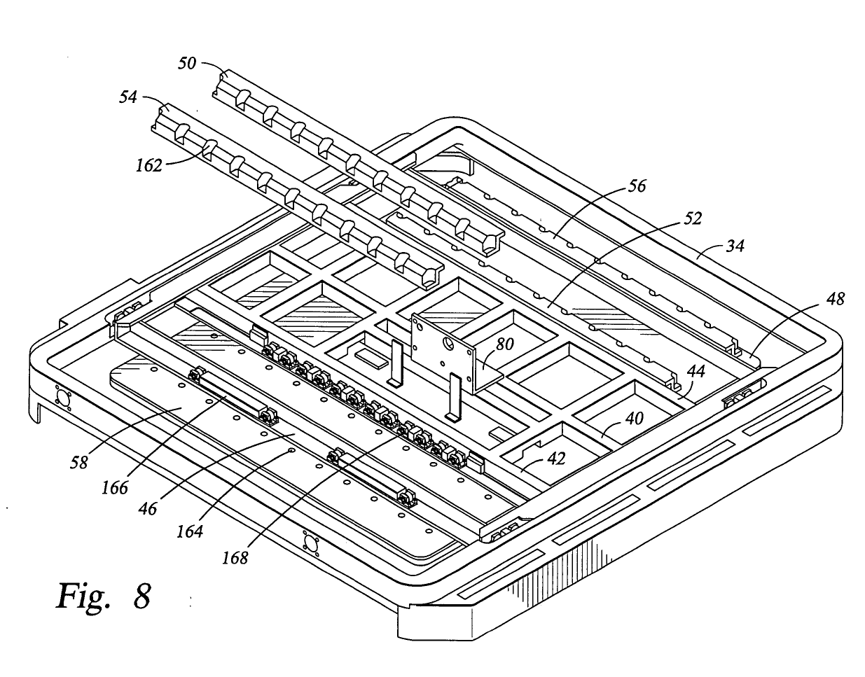

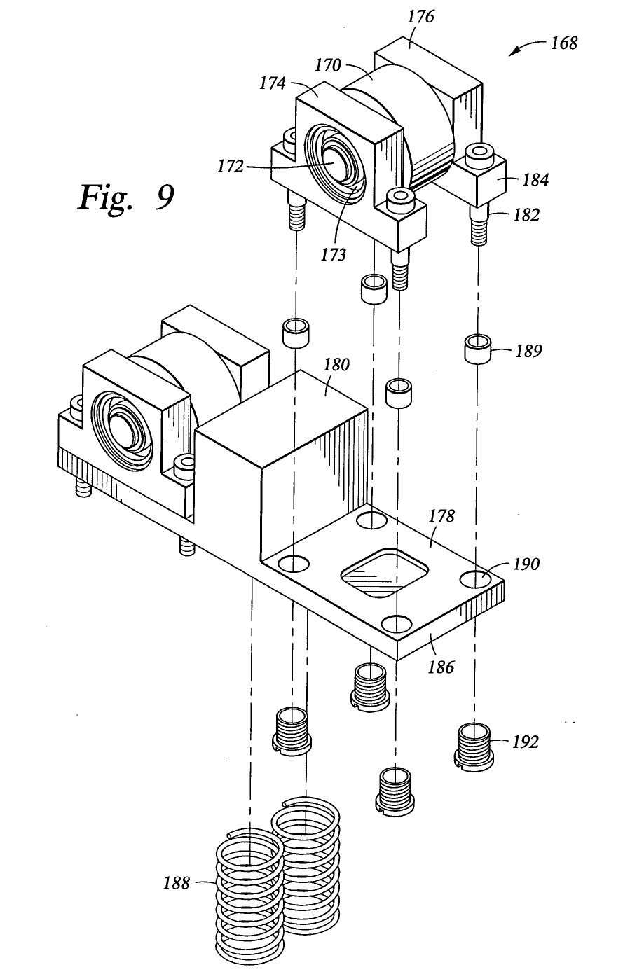

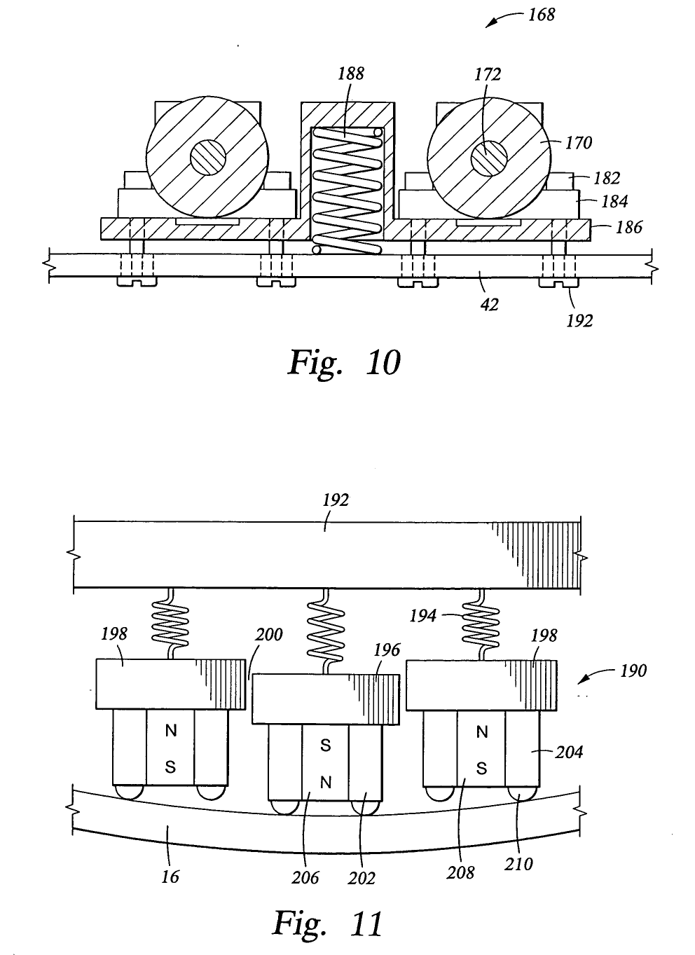

A second embodiment of a spring-loaded support places the spring loading between the cylindrical rollers and the rails as illustrated in the orthographic views of FIGS. 8 and 9 and the cross-sectional view of FIG. 10. In this embodiment, the rails 46, 50, 52, 56 are fixed to the magnetron plate 48 by screws passing through pass holes formed at the bottom of cutouts 162 in the rails 50, 52, 54, 56 and threaded into tap holes 164 tapped into the top of the magnetron plate 58. However, spring-loaded roller assemblies 166, 168 are spring-loaded on top of the struts 42, 44, 46, 48. Although the roller assemblies 166 on the outer struts 46, 48 have a different configuration though the same function as the roller assemblies 168 on the inner struts 42, 44, the difference arises from a desire to implement the invention on a pre-existing gantry 40. Alternatively, all roller assemblies 166, 168 may have a same form and structure. The roller assemblies 166, 168 rollably support the rails 50, 52, 54, 56 and its suspended magnetron plate 58 to allow the magnetron plate 58 to roll along the direction of the rails.

As better shown in FIGS. 9 and 10, each roller assembly 168 includes two cylindrical rollers 170 having respective shafts 172 freely rotating in bearings 173 mounted in opposed bearing housings 174, 176. In the prior embodiment as well as in the Tepman configuration, the bearing housings 174, 176 were fixed with screws to the struts. However, in this embodiment, the bearing housings 174, 176 and hence the cylindrical rollers 170 are mounted in pairs within a T-shaped spring housing 178 having a central spring chamber 180 between two bottom portions of a base 186. The spring chamber 180 accommodates two springs 188. Corresponding spring chambers in the roller assemblies 168 accommodate six springs 188. Shoulder screws 182 have heads engaged above tabs 184 in the bearing housings 174, 176 and have shafts passing through holes in the tabs 184 and in the base 186 of the spring housing inside of bushings 189 in through holes 190 in the base 186. The shoulder screws 182 have threaded ends which are threaded into internally and externally threaded inserts 192 threaded into and held in the strut.

Tightening of the shoulder screws 182 compresses the springs 188 between the strut and the top of the spring chamber 180. However, the tightening is not completed to the extent that the base 186 is forced against the strut. Instead, the base 186 and the entire spring assembly 168 is allowed to float above the strut with a gap determined by the torque applied to the shoulder screws 182 and the weight of the partially supported magnetron. The spring torque thus determines in part the fraction of the magnetron weight supported by the gantry. The gap may vary as the magnetron follows the shape of the target. As a result, the split of magnetron weight between the target and the gantry depends on the local height of the target.

In the embodiment of FIGS. 8, 9, and 10, the magnetron plate may be partially supported on the target by roller ball mechanism described with reference to FIGS. 5, 6, and 7 or by other rolling, sliding, or gliding mechanisms, thus dividing the magnetron weight between the gantry and the target.

Other spring-loaded suspension mechanisms may be used to partially support the magnetron from a horizontally movable carriage. For example, cylindrical rollers may be coupled to the bottom of the rails by partially compressed springs and roll on the struts.

The division of support for the magnetron between the gantry and the target allows the heavy magnetron to follow the shape of the target as it is being scanned across the back without unduly flexing the thin target. The gantry should support at least 50% of the weight of the magnetron. Preferably, the target supports less than 25% of the weight and more preferably less than 15%. The multiple independent spring-loaded supports allows the magnetron to not only move vertically but also to tilt if the portion of the target it is tracking is sloping. The partial support of the magnetron on the target allows the magnetron to track the shape of a bowed or otherwise deformed target. Thereby, the variation of gap between the magnetron and the non-planar target may be significantly reduced. Further, the design magnitude of the gap may also be reduced to increase the effective magnetic field adjacent the sputtering face of the target.

Another embodiment, very schematically illustrated in the cross-sectional view of FIG. 11 provides a flexible magnetron 190 which can follow and conform to a sloping shape of the target 16. A support plate 192 partially supports through springs 194 a patterned first magnetic yoke plate 196 and a patterned second magnetic yoke plate 198 interleaved with the first yoke plate 196. The two yoke plates 196, 198, each composed of a magnetizable material, such as magnetically soft steel or stainless steel, are separated by a sufficiently small gap 200 that the two yoke plates 196, 198 form a single magnetic yoke. For example, the gap 200 may be ⅛″ (3.2 mm) and is preferably no more than 6.4 mm. The two yoke plates 196, 198 support retainers 202, 204 for aligning anti-parallel magnets 206, 208, which are held by their magnetic field to the respective yoke plates 196, 198. The first yoke plate 196 and its retainers 202 and magnets 206 form a first magnetic pole of the magnetron 190 and the second yoke plate 198 and its retainers 204 and magnets 208 form an opposed second magnetic pole. Roller balls 210 rotate on the bottoms of the retainers 202, 204 and, depending upon the local slope of the target 16, some or all of the roller balls 210 engage and roll on the target 16. As a result, each local part of the magnetron is separately partially supported from above by one of the springs 194 and from below by one or two of the roller balls 210. In the direction perpendicular to the illustration, the yoke plates 196, 198 are generally continuous but are still fairly flexible so that multiple springs 194 and roller balls 210 positioned along the yoke plates 196, 198 allow to bend and conform to the local shape of the target.

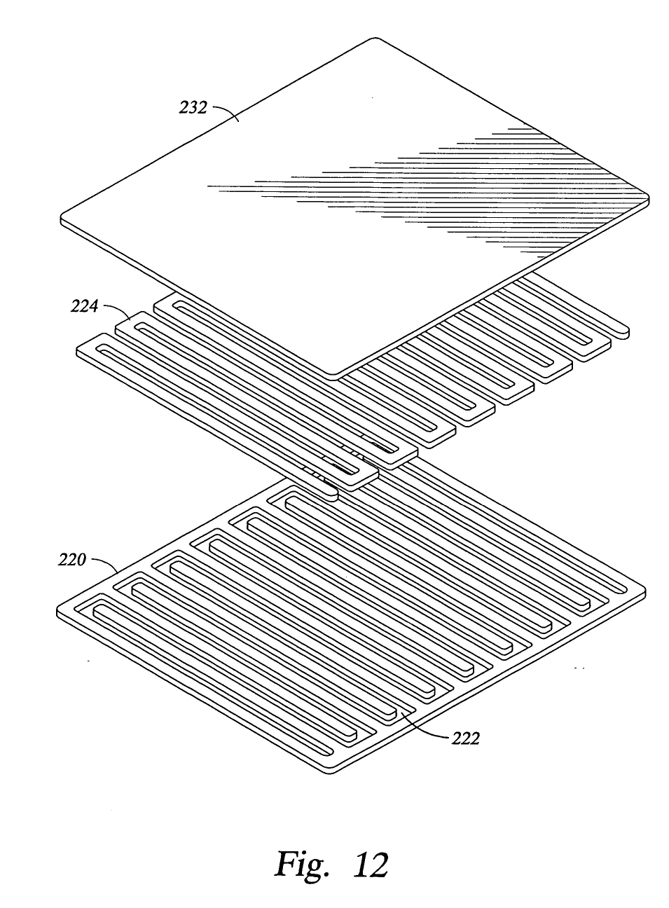

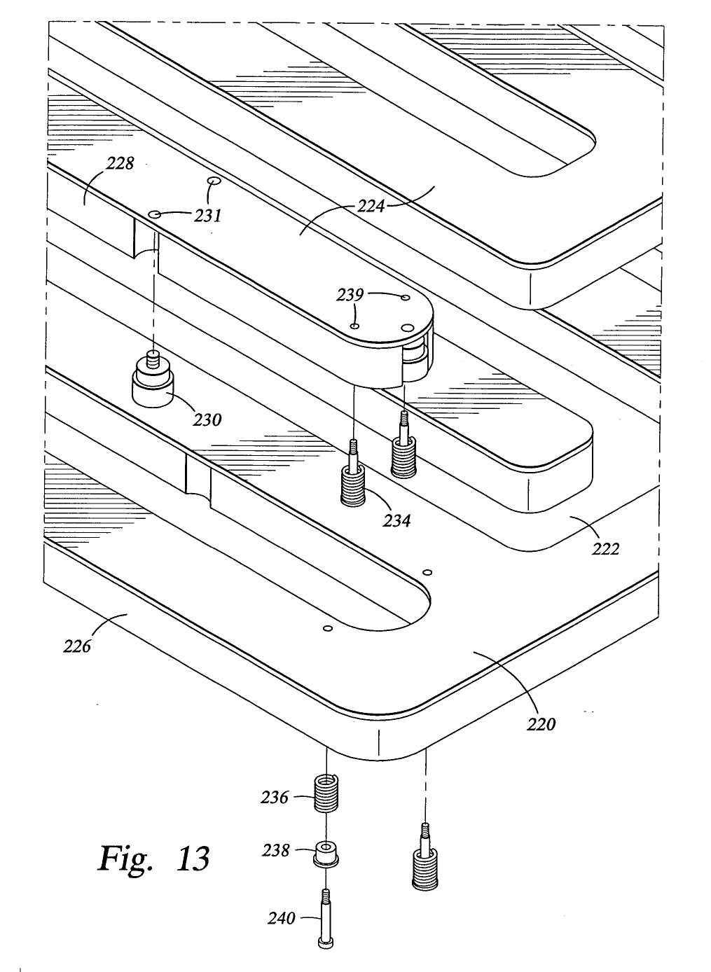

The magnetron system is more specifically illustrated in the orthographic view of FIG. 12 and the exploded orthographic view of FIG. 13. A patterned outer yoke plate 220 has a continuous outer periphery but a serpentine slot 222. A patterned inner yoke plate 224 has a long serpentine shape that fits within the slot 222 with the predetermined gap 200 between them. The illustrated serpentine shapes are folded. Other serpentine shapes include a rectangularized spiral or parallel linear racetracks. Retainers 226, 228 are screwed on the two yoke plates 220, 224 to align unillustrated magnets. Transfer ball assemblies 230 (that is, roller ball assemblies) are fixed to the bottoms of the two yoke plates 220, 224 by being threaded into tapped holes 231 in the yoke plates 220, 224 and have roller balls protruding beyond the retainers 226, 228 to roll on the back side of the target. The yoke plates 220, 224 are partially suspended from a support plate 232. Spring assemblies 234 spring couple the support plate 232 and the yoke plates 220, 224. Each spring assembly 234 includes a spring 236 positioned beneath the respective yoke plate 220, 224, a spring retainer cap 238 at the bottom of the spring 236, and a screw 240 having a screw head engaging the bottom of the spring retainer cap 238, a screw body passing through the spring 238 and a pass hole 239 in the yoke plate 220, 224, and a threaded screw end threaded into the support plate 232 so as to partially suspend the magnetron from the support plate 232 through the springs 236. An exemplary spring strength is 7.4 lb/in (1.7 Nt/cm). The support plate 232 in turn may be supported on and fixed to the gantry configured to scan in two dimensions, as has been described with reference to FIG. 2. Although a solid support plate 232 is illustrated, it may be divided into slats, each supported on the gantry.

The patterned yoke plates 220, 224 have central portions that are relatively flexible so that they can deform to follow the shape of the target on which they are partially supported. That is, the magnetron as a whole is deformable in two dimensions and can conform to the local shape of the target. Furthermore, the desired flexibility allows the magnetron structure as a whole to be relatively lightweight since rigidity is no longer a desired design goal. Since the support plate 232 may be somewhat flexible, it may be composed of aluminum having a thickness of ½″ (12.7 mm). The yoke plates 220, 224 do not need to contribute much structural strength and may be formed from magnetically soft steel plates having a thickness of ⅜″ (9.5 mm) so that the gap 200 is less than 70% of the thickness of the yoke plates 226, 228 structurally separated by it but magnetically coupled across it. The retainers 226, 228 should be designed to be both lightweight and relatively flexible. Overall, the weight of the magnetron assembly of FIGS. 12 and 13 suspended from the gantry is significantly reduced, for example, by 10%, from that of a magnetron assembly based upon a rigid and solid yoke plate also acting as a support plate.

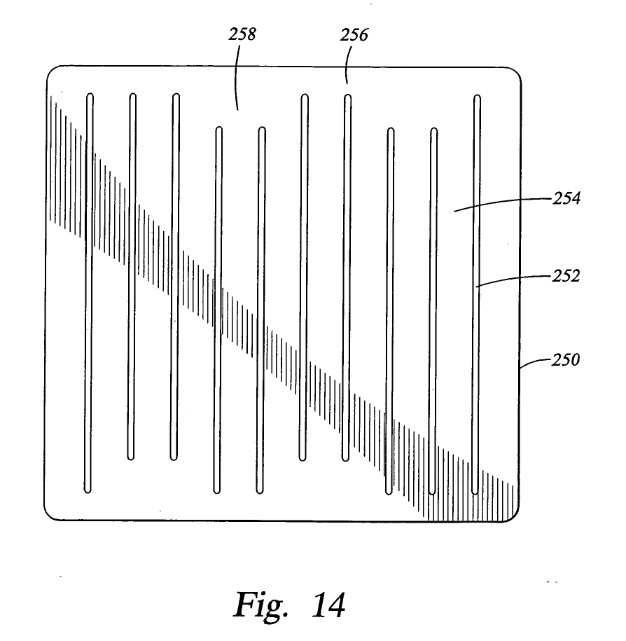

A similar flexibility can be achieved with a unitary patterned yoke plate 250 illustrated in the plan view of FIG. 14 having parallel slots 252 extending nearly but not completely across the plate 250. Aisles 254 between the slots 252 and the uninterrupted peripheral region 256 support the retainers and the magnets of constituting the two opposed poles. Wider peripheral regions 258 support both poles, between which the plasma track is formed. The slots 252 are narrow enough to magnetically couple adjacent aisles but still allow the aisles 254 cantilevered between two parts of the peripheral region 256 to more easily flex. The springs assemblies 234 and transfer ball assemblies 230 of FIG. 13 may be similarly attached to the unitary yoke plate 250.

Another embodiment for achieving a flexible magnetron which can track over a deformed target is particularly useful when the target is divided into parallel target strips, which may be separated by raised anodes or other features. A separate magnetron is dedicated to each target strip. Inagawa et al. describe the ganged scanning of multiple magnetrons in provisional application 60/835,671, filed Aug. 4, 2006. Le describe improvements to the magnet distribution in each of magnetrons in provisional application 60/835,681, also filed Aug. 4, 2006. Both references are incorporated herein by reference.

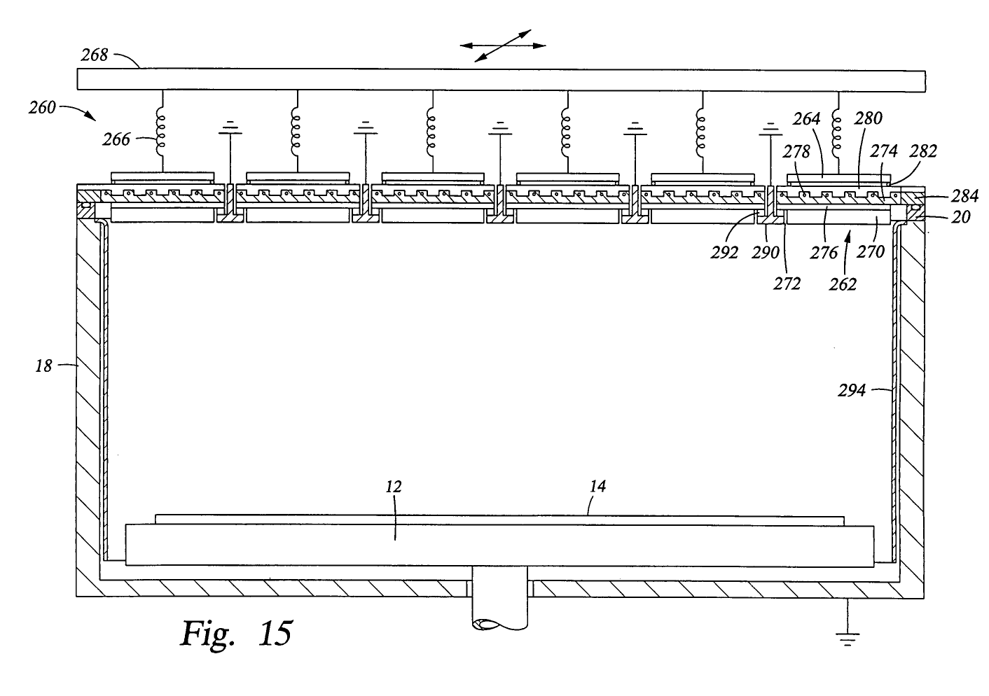

Such a sputtering chamber 260 illustrated in the cross-sectional view of FIG. 15 includes multiple strip targets 262 and associated strip magnetrons 264. Separate spring mechanisms 266 partial support the different magnetrons 262 from a common support plate 268, which provides a common two-dimensional scanning motion. Each strip target 262 includes a target layer 270 having axially extending side indented borders 272. The target layer 270 of each strip is bonded to a respective strip backing plate 274 through a bonding layer 276 of approximately the same horizontal extent as the strip target layer 270. The strip backing plate 274 is formed with ridges through which cooling channels 278 are bored. A light-weight filling material layer 280, which may be a dielectric, fills the valleys between the ridges and is planarized above the ridges to form a flat surface on which roller balls 282 of the strip magnetrons 264 roll. The strip targets 262 are fixedly supported on the chamber 18 by an unillustrated mechanical structure including an apertured rack 284 supporting peripheries of the strip backing plates 274. The strip targets 262 are all electrically powered to excite the plasma of the sputter working gas.

The strip targets 262 advantageously allow axially extending grounded anodes 290 to protrude to the sputtering surface of the target while held within the gaps formed by the indented borders 272 between two neighboring strip targets 262. The grounded anodes 290 are electrically isolated from the strip backing plate 166 by an insulator 302, which may be formed from an extension of the filling material layer 280, and may also provide a vacuum seal between the high-vacuum sputtering chamber 18 and the low-vacuum back chamber 22. The strip targets 262, on the other hand, are electrically powered and are isolated from the anodes 290 by the insulators 292 and other gaps smaller than the plasma dark space to act as cathodes in generating the sputtering plasma. The chamber 260 additionally includes an electrically grounded shield 294 to protect the chamber sidewalls from deposition while also acting as an anode. The isolator 20 electrically isolates the chamber 18 from the rack 284 and the strip backing plates 274 it supports. However, the electrical isolation may alternatively be provided between the rack 284 and each of the different strip targets 262 it supports.

The support plate 268 is scanned in a pattern so that all the magnetrons 264 are scanned in substantial synchronism in the same pattern. The principal variation between the magnetrons' paths arise from the resilience of their support on the support plate. The scanned patterned may extend along one of the orthogonal x- and y-axes, or be a two-dimensional x/y scan pattern, for example, an O-shaped pattern having portions extending along the x- and y-axes, an X-shaped pattern having portions extending along two diagonal, a Z-shaped pattern extending along opposed parallel sides and a diagonal therebetween, or other complex patterns. Only a single scan mechanism is required for the multiple magnetrons although, of course, plural sets of multiple magnetrons and associated scan mechanisms are possible.

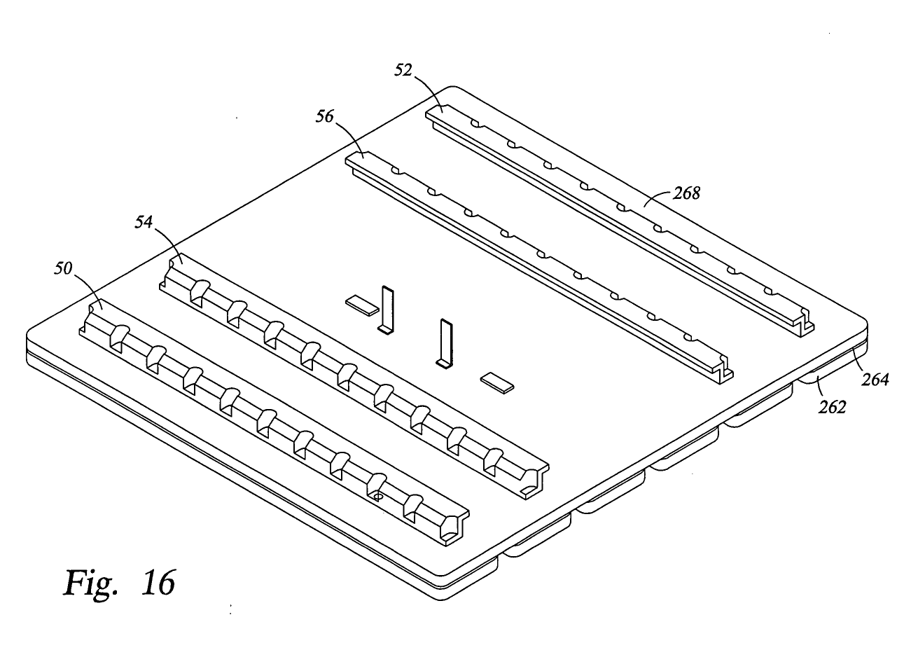

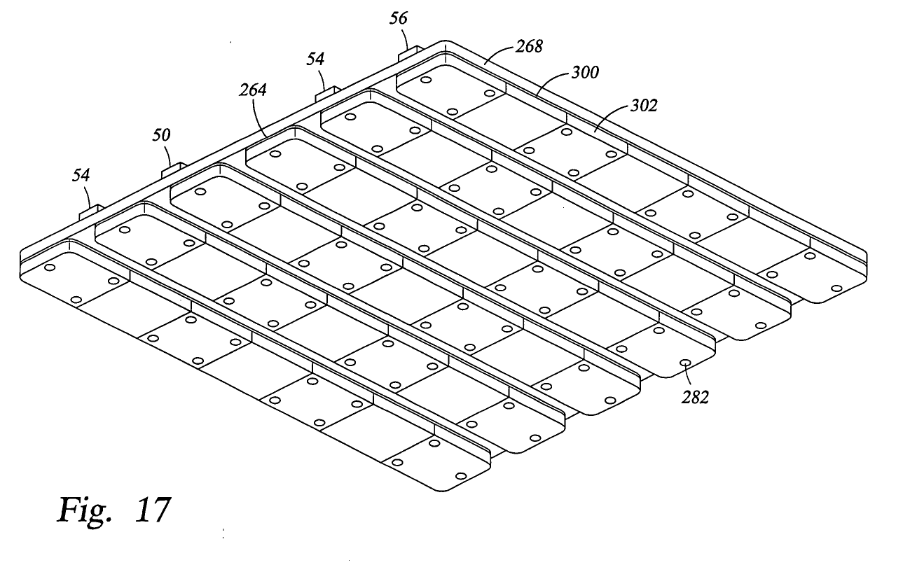

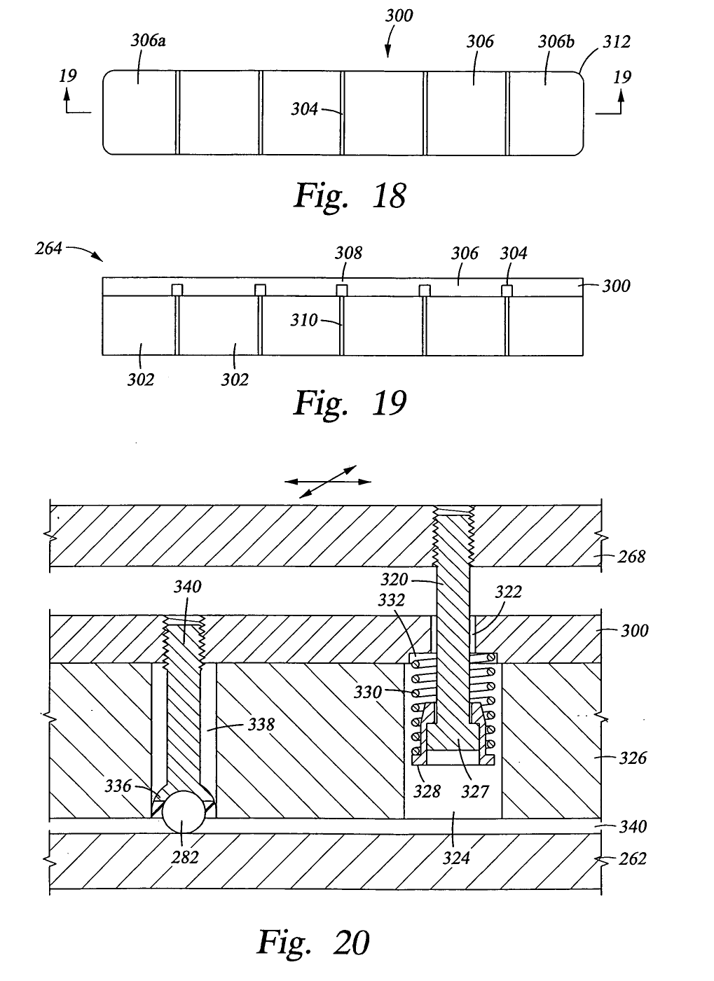

As illustrated in the orthographic view of FIG. 16 generally from above, the previously mentioned gantry rails 50, 52, 54, 56 fixedly support the support plate 268 on its top side instead of the magnetic yoke plate 58 of the previous embodiment of FIGS. 2 and 3. Preferably the support plate 268 is non-magnetic and may be composed of aluminum. As illustrated also in the orthographic view of FIG. 17, the support plate 268 in turn resiliently supports through the spring mechanisms 266 on its bottom side the multiple magnetron strips 264 through parallel yoke strips 300 composed of magnetic material. Each yoke strip 300 supports along the axis of the strip 300 multiple retainer sections 302, which are screwed to the yoke strip 300. As illustrated in the plan view of FIG. 17 and the cross-sectional view of FIG. 18, the front or bottom side of each yoke strip 300 is transversely scored by machining or other means to form parallel grooves 304 extending partially through the yoke strip 300 in its front side to form yoke sections 306, including end yoke sections 306a, 306b, joined only by a thin torsion leaf 308 such that the individual yoke sections 306 are relatively rigid but are flexibly connected. It is also possible to place the grooves 304 on the back or top side of the yoke strip 300. The previously described retainers for aligning the magnets are screwed to and are supported on the bottom of the yoke strip 300 in retainer sections 302 but are divided across retainer gaps 310 such that no retainer is fixed to two neighboring yoke sections 306. Thereby, the retainers do not significantly reduce the flexibility of the yoke strip 300.

The yoke strip 300 is formed with curved corners 312 generally conforming to the outer shape of the corner retainers and the outermost portions of the plasma track are developed somewhat farther inwardly. The corner shaping reduces the amount of sputtered target material redeposited on the target.

If the magnetron is relatively flexible vertically, its resilient support from the support plate 268 should be somewhat angularly flexible. Accordingly, as illustrated in the cross-sectional view of FIG. 20, a spring-loaded support may include a machine screw 320 screwed into the bottom of the support plate 268. The body of the screw 320 passes through a widened through hole 322 in the yoke strip 300 into an access hole 324 of a retainer 326. The access hole 324 allows tool access to rotate the screw 320. A head 327 of the screw 320 supports a flanged washer cup 328. A compression spring 330 is captured between a flange of the washer cup 328 and a recess 332 formed on the bottom of the yoke plate 264 around the through hole 322. The compression spring 330 resiliently and partially supports the yoke strip 300 from the support plate 268 and associated retainers and magnets. However, the spring support of the multiple strip magnetrons are not limited to that of FIG. 20 and other types may be used such as those previously described.

On the other hand, the roller ball 282 partially supports the yoke strip 300 on the back of the strip target 262. The roller ball 282 is incorporated into a roller ball assembly 336 such as that illustrated in FIG. 5. The roller ball assembly 336 is positioned within an aperture 338 in the retainer 326 and a threaded stud 340 is screwed into the yoke strip 300 to a depth such that a portion of the roller ball 282 extends beyond the bottom of the retainer 326. Alternatively, the roller ball assembly 336 may fit within a recess in the retainer 326 and be screwed into a tapped hole near the top side of the retainer 326. When the screw 320 associated with the spring 330 is screwed further into the support plate 268, the spring 330 is compressed to cause the support plate 268 to support an increased fraction of the weight of the magnetron and remove the weight from the roller ball 282 and the strip target 262 supporting it. Thereby, the yoke strip 300 and attached retainer 326 and magnets aligned by the retainer 326 are resiliently supported by the support plate 268 through the spring 330 such that only a controlled portion of the weight of the magnetron is rollably supported on the target assembly through the roller ball. Even though the strip target 262 may support only a small fraction of the magnetron weight, the magnetron still maintains a fixed height or separation over the target assembly, which may be deformed for whatever reasons.

Each yoke section 306 of the yoke strip 300 is preferably supported by at least two such spring-loaded supports. Thereby, the yoke strips 300 are flexible between themselves because there is no rigid connection between them but, because of the flexible torsion leaves 308, the yoke strips 264 provide sufficient alignment, that a reduced number of spring-loaded supports may be used for each sections. Also, the yoke sections 306 are relatively flexible between themselves because of the reduced rigidity across the torsion leaves 308 and their independent resilient support and the reduced angular rigidity of the support screws 320 having only their tips fixed to the support plate 268. As a result, the magnetron sections separately track the shape of the bowed or otherwise deformed target strips while being primarily supported from the gantry.

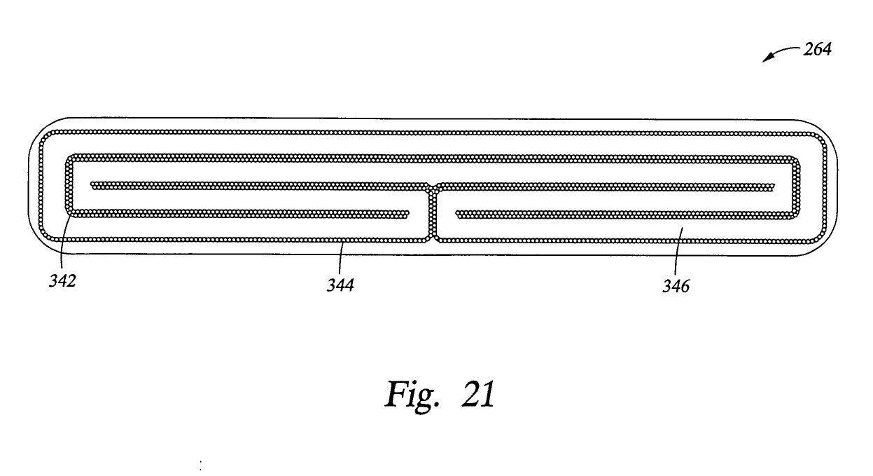

Although not specifically illustrated in FIG. 17, the magnet distribution of the strip magnetrons 264 is much narrower than that illustrated in FIG. 7, for example having an axial length of at least four times the transverse width. The magnets may form a single linear racetrack having closed gap between the poles producing a corresponding plasma track with two long parallel portions connected by two 1800 curved ends. More preferably, however, each strip magnetron 264 may be formed, as illustrated in the bottom plan view of FIG. 21 as a two-level serpentine magnetron in which the two ends of the racetrack shape are folded in the same direction and the ends meet in the middle. Specifically, the strip magnetron 264 includes a series of unillustrated retainers screwed into the yoke strip 300. Each of the retainers are typically only a fraction of the length of the strip magnetron 264 and preferably have ends near the junctions between the yoke sections 306 so as to not degrade the flexibility of the strip magnetrons 264. The retainers have cylindrical holes or facing serrated edges defining between them inner magnet positions 342 and outer magnet positions 344, into which cylindrical magnets of opposed polarities respectively are inserted. Each of the sets is arranged in a continuous distribution such that the inner magnet positions 342 define an inner magnetic pole of one polarity and the outer magnet positions 344 define an outer magnetic pole of the opposite polarity surrounding the inner magnet pole. In this embodiment, for the most part, the magnets are arranged in close-packed double rows in the interior of the magnetron but in a single row at the periphery of the magnetron. A gap 346 between the inner and outer magnetic poles has a nearly constant width and is formed in a closed shape or loop which corresponds generally to the plasma track the magnetron creates on the sputtering face of the target. However, the retainers may have extra magnet positions inside or outside of the rows, especially near the comers of the gap 346 to tailor the magnetic field distribution and intensity. The roller balls assemblies and spring supports are not illustrated in FIG. 21 but generally fit into or between the retainers away from the magnet positions 342, 364 and may be in the area of the gap 346. Le provides a more complete description in the aforecited provisional application.

The separately supported strip magnetrons are particularly useful for a separated target comprising multiple strip targets. However, the separately supported strip magnetrons may also be used with a substantially uniform and unitary target not introducing structure between the strip magnetrons. Thereby, the strip magnetrons can be scanned over a larger fraction of the target.

The flexibility of the strip magnetrons 264, however, introduces the problem of keeping the different yoke strips 300 and associated separate magnetrons aligned with each other in the horizontal directions while vertical motion is allowed between the yoke strips 264 and along their longitudinal axes. Centering pins can alleviate this problem. As illustrated in the plan view of FIG. 22, the bottom side of one yoke strip 300 is resiliently supported at an end of the support plate 260. This figure does not illustrated the retainers. Three roller ball assemblies 336 are mounted in each of the end yoke sections 306a, 306b to provide three point rolling support on the back of the strip target 262 for those yoke sections 306a, 306b. Inner ones of the yoke sections 306 may contain fewer or no roller ball assemblies 336 since they are supported laterally on both sides by neighboring yoke sections 270. In one embodiments, the inner yoke sections 270 alternate between 0 and 4 roller ball assemblies 336.

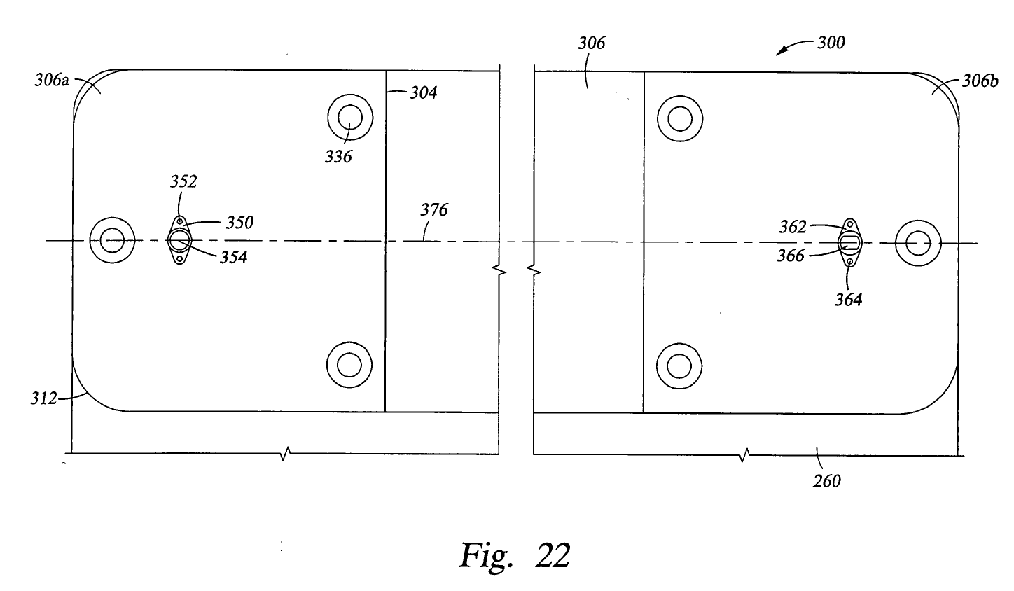

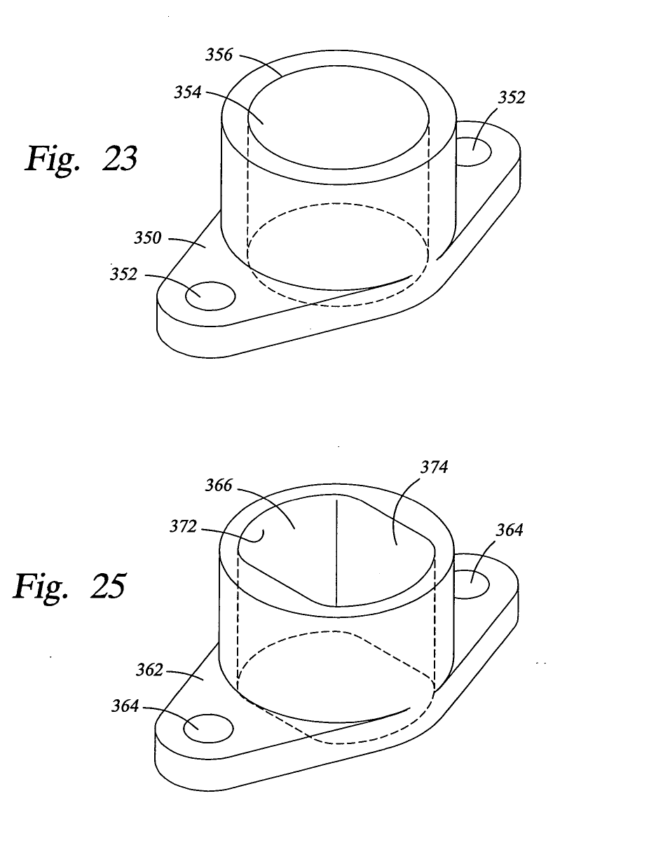

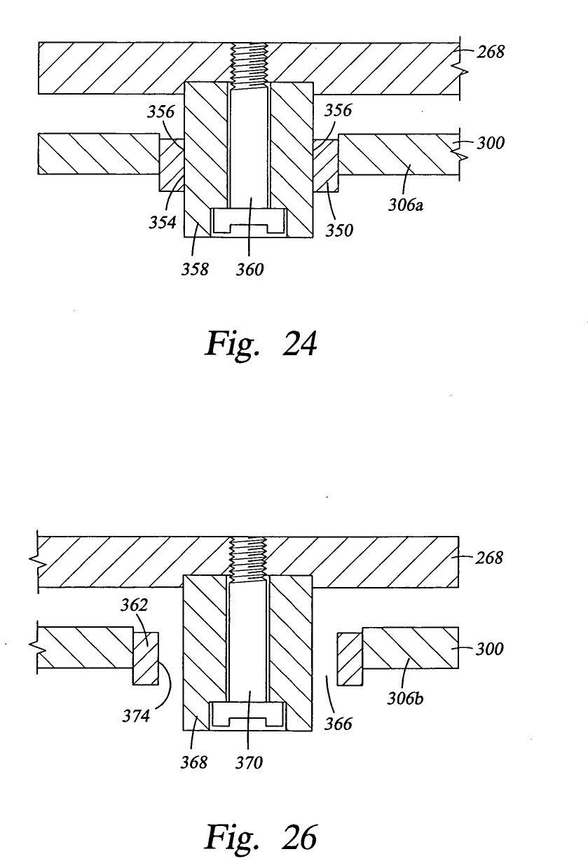

A positioning bracket 350, also illustrated in the orthographic view of FIG. 23, is mounted into a recess on the bottom of the first end yoke section 306a of the yoke strip 300 by screws passing through pass holes 352 in the positioning bracket 350 and screwed into the tapped holes in the first end yoke section 306a. The positioning bracket 350, as further illustrated in the cross-sectional view of FIG. 24, includes a vertically extending circular guide hole 354 with a circular sidewall 356 to closely accept a circular centering pin 358 fixed to the support plate 268 by a screw 360. The centering pin 358 may move vertically in the guide hole 354 to accommodate the flexible movement of the magnetron. The combination of positioning bracket 354 and centering pin 358 two-dimensionally fixes one point of the yoke strip 300 to a point of the support plate 268 but allows the yoke strip 300 to rotate about that point.

On the other hand, a clocking bracket 362, illustrated in both the bottom plan view of FIG. 22 and the orthographic view of FIG. 24 is similarly mounted into a recess on the bottom of the second end yoke section 306b of the yoke strip 300 by screws passing through pass holes 364 and screwed into tapped holes in the second end yoke section 306b. Preferably the separations between the pass holes 352, 364 of the two brackets 350, 362 are different so that they cannot be mistakenly interchanged or two of the same type be used on one yoke strip 300. The clocking bracket 362, as further illustrated in the cross-sectional view of FIG. 25 include a vertically extending elongated guide hole 366 to accept a circular second centering pin 368 fixed to the support plate 268 by a screw 370. Again, the centering pin 368 may move vertically in the guide hole 366 to accommodate the flexible movement of the magnetron. The elongated guide hole 366 includes two semi-circular side walls 372 of radius slightly larger than the radius of the second centering pin 336 and two opposed flat side walls 374 connecting the semi-circular side walls 372 and separated by a distance again slightly larger than the radius of the second centering pin 368. When mounted on the yoke strip 300, the flat sidewalls 374 and the longitudinal axis of the elongated guide hole 366 extend parallel to a strip central axis 376 of FIG. 22 connecting centers of guide holes 350, 366 of the positioning and clocking brackets 350, 362 so that the guide hole 366 only loosely captures the second centering pin 368 in that direction. As a result, the second centering pin 368 can move along the strip central axis 376. On the other hand, the elongated guide hole 366 closely captures the second centering pin 368 in the direction perpendicular to the strip central axis 376 thereby restraining movement perpendicular to the strip central axis 376. As a result, each of the yoke strips 300 is aligned to the respective axis between the centers of the two centering pins 358, 368 at their attachment to the support plate 268 but the yoke strips 300 can each move slightly along the respective axis as their yoke sections 270 flex relative to one another. That is, the clocking bracket 350 controls the angular orientation of the yoke strip 300 about the positioning bracket 350. It is understood that the axis connecting the two centering pines need not be a central longitudinal axis of the strip. It is also understood that the location of one or both sets of centering pins and brackets may be reversed between the support plate and the yoke plate. Also, the centering structure may be incorporated into a non-magnetic plate fixed to the yoke.

Although the springs described in the above embodiment are all spiral compression springs, other forms of springs may be used including tension springs and leaf springs.

The invention thus allows closer tracking of the magnetron with a thin non-planar target and a reduction in the weight of the magnetron assembly being scanned, both features becoming increasingly important for sputter chambers designed for the larger flat panels being planned.

1. A flexible magnetron assembly, comprising:
a support member movable in at least one direction;
a flexible magnetron resiliently supported on the support member and including a plurality of first magnets of a first magnetic polarity and a plurality of second magnets of a second opposed magnetic polarity fixed to the flexible magnetron and forming a closed gap between them; and
at least one roller disposed on a side of the magnetron opposite the support member to slidingly engage a back side of a sputtering target assembly.

2. The assembly of claim 1, wherein the flexible magnetron includes a flexible yoke magnetically coupling the first and second magnets.

3. The magnetron of claim 2, wherein the flexible yoke comprises a magnetic plate extending along a first axis and being scored on a least one side thereof along a second axis perpendicular to the first axis.

4. A magnetron system, comprising a plurality of the magnetrons of claim 1 commonly but separately resiliently supported from the support member.

5. The magnetron system of claim 4, wherein the at least one roller comprises at least one respective roller disposed on each of the plurality of magnetrons.

6. The magnetron of claim 1, further comprising means to fix a first point of the magnetron to the support plate and to allow a second point of the magnetron displaced from the first point along an axis to move along the axis but not move perpendicularly to the axis.

7. The magnetron of claim 6, wherein the means are coupled between a flexible yoke and the support plate supporting the flexible yoke.

8. A flexible magnetron assembly, comprising:
a support member movable in at least one direction;
a plurality of flexible magnetrons each separately resiliently supported on the support member and including a plurality of first magnets of a first magnetic polarity and a plurality of second magnets of a second opposed magnetic polarity fixed to the flexible magnetron and forming a closed gap between them; and
at least roller disposed on a side of each of magnetron opposite the support member to slidingly engage a back side of a sputtering target assembly.

9. The assembly of claim 8, wherein each of the magnetrons comprise a yoke strip extending along a first axis and including scores partially extending through the yoke strip along a second axis perpendicular to the first axis.

10. The assembly of claim 8, further comprising a scan mechanism scanning the support member in two dimensions parallel to a sputter surface of the sputtering target assembly.

11. The assembly of claim 8, wherein the flexible magnetrons are arranged along a first direction and further comprising a centering mechanism associated with each of the flexible magnetrons and coupled to the support member for centering the flexible magnetrons along a second direction transverse to the first direction.

12. A centered magnetron, comprising:
a support plate;
a magnetron extending along a first axis and resiliently supported from the support plate;
a positioning apparatus coupled between the support plate comprising a first centering pin and a circular guide hole closely and rotatably capturing the first centering pin; and
a clocking apparatus coupled between the support plate and displaced from the position apparatus along the first axis and comprising a second centering pin and an elongated guide hole closely capturing the second centering pin along a second axis perpendicular to the first axis and allowing movement of the second centering pin along the first axis.

13. The magnetron of claim 12, wherein the centering pins are fixed to the support plate.

14. A magnetron system, comprising a plurality of the magnetrons of claim 12 each resiliently supported from the support and each having its own positioning and clocking apparatus.

15. A method of operating a PVD system, comprising moving a magnetron including a flexible yoke along a back of a sputtering target.

16. The method of claim 15, wherein the magnetron is at least partially supported on the target such that the magnetron conforms to a shape of the target.

17. The method of claim 15, comprising moving a plurality of said magnetrons along a back of the sputtering target which are at least partially supported on the target such that each of the magnetrons conform to a shape of the target as they move.

18. A method of operating a PVD system including a plurality of magnetrons at least partially supported from a support plate, the method comprising scanning the support plate in a two dimensional pattern and further comprising for each of the magnetrons during the scanning:
a first step of fixing respective first positions of the magnetrons to corresponding second positions on the support plate while allowing the magnetrons to rotate about the second positions; and
a second step of dynamically angularly fixing respective third positions of magnetrons with respect to respective axes separating the first and third positions.
